(19) United States
(12) Patent Application Publication
(10) Pub. No.: US 2025/0167103 A1
(43) Pub. Date: May 22, 2025

(54) LOW RESISTANCE VIA STRUCTURE

(71) Applicant: INTERNATIONAL BUSINESS MACHINES CORPORATION, ARMONK, NY (US)

(72) Inventors: Oscar van der Straten, Guilderland Center, NY (US); Chih-Chao Yang, Glenmont, NY (US)

(21) Appl. No.: 18/510,720

(22) Filed: Nov. 16, 2023

(51) Int. Cl. H01L 23/522; H01L 21/768

(52) U.S. Cl. CPC H01L 23/5226; H01L 21/76816; H01L 21/76849

(57) ABSTRACT

A homogeneous interconnect structure including a first region vertically aligned above a second region, the first region includes a first width at an upper horizontal surface and a second width at a lower horizontal surface, the first width is greater than the second width, the second region includes a third width, the third width is greater than the second width. A homogeneous interconnect structure including a first region vertically aligned above a second region, the first region includes a first width at an upper horizontal surface and a second width at a lower horizontal surface, the first width is greater than the second width, and the second region includes a third width at an upper horizontal surface and a fourth width at a lower horizontal surface, the third width is less than the fourth width.

### BACKGROUND

The present invention generally relates to semiconductor structures, and more particularly to a via structure with low resistance.

Back end of line (BEOL) is the portion of integrated circuit where the individual devices (transistors, capacitors, resisters, etc.) get interconnected with one or more metallization layers. The BEOL begins above the front-end-of-line region which contains the devices themselves. In general, the BEOL includes contacts, insulating layers (dielectrics), metal levels, and bonding sites for chip-to-package connections and wiring for metal lines. For multi-level interconnection of advanced semiconductor devices, metal via structures are used to enable metal-to-metal contact to the levels below. Via structures typically include both a main conductor material and several suitable nucleation, liner and/or barrier layers. These layers ensure adequate adhesion to the surrounding dielectric as well as good nucleation and growth of the main conductor material. The liner and barrier materials typically exhibit high resistivity, and the presence of such high-resistivity liner and barrier layers in a via structure results in high via resistance which negatively impacts device performance. In addition, the various interfaces formed by these liner and barrier layers can add resistance components to the overall via resistance. There is a need for via structures with reduced via resistance.

### SUMMARY

According to an embodiment of the present invention, a semiconductor structure is provided. The semiconductor structure including a homogeneous interconnect structure embedded in a dielectric layer, where the homogeneous interconnect structure includes a first region vertically aligned above a second region, the first region includes a first width at an upper horizontal surface of the first region and a second width at a lower horizontal surface of the first region, where the first width is greater than the second width, and the second region includes a third width, where the third width is greater than the second width.

According to an embodiment of the present invention, a semiconductor structure is provided. The semiconductor structure including a homogeneous interconnect structure embedded in a dielectric layer, where the homogeneous interconnect structure includes a first region vertically aligned above a second region, the first region includes a first width at an upper horizontal surface of the first region and a second width at a lower horizontal surface of the first region, where the first width is greater than the second width, and the second region includes a third width at an upper horizontal surface of the second region and a fourth width at a lower horizontal surface of the second region, where the third width is less than the fourth width.

According to an embodiment of the present invention, a method is provided. The method including forming a homogeneous interconnect structure embedded in a dielectric layer, where the homogeneous interconnect structure includes a first region vertically aligned above a second region, the first region includes a first width at an upper horizontal surface of the first region and a second width at a lower horizontal surface of the first region, where the first width is greater than the second width, and the second region includes a third width, where the third width is greater than the second width.

### BRIEF DESCRIPTION OF THE DRAWINGS

The following detailed description, given by way of example and not intended to limit the invention solely thereto, will best be appreciated in conjunction with the accompanying drawings, in which:

FIG. 1 is a cross-sectional view of a structure shown during an intermediate step of fabrication, according to an embodiment of the invention;

FIG. 2 is a cross-sectional view of the structure and illustrates deposition and patterning of an inter-layer dielectric layer, according to an embodiment of the invention;

FIG. 3 is a cross-sectional view of the structure and illustrates patterning a dielectric cap layer, according to an embodiment of the invention;

FIG. 4 is a cross-sectional view of the structure and illustrates further patterning of the dielectric cap layer, according to an embodiment of the invention;

FIG. 5 is a cross-sectional view of the structure and illustrates deposition of a first barrier layer, according to an embodiment of the invention;

FIG. 6 is a cross-sectional view of the structure and illustrates removal of a portion of the first barrier layer, according to an embodiment of the invention;

FIG. 7 is a cross-sectional view of the structure and illustrates deposition of a second barrier layer, according to an embodiment of the invention;

FIG. 8 is a cross-sectional view of the structure and illustrates removal of a portion of the second barrier layer, according to an embodiment of the invention;

FIG. 9 is a cross-sectional view of the structure and illustrates deposition of a conductive material, according to an embodiment of the invention;

FIG. 10 is a cross-sectional view of the structure and illustrates planarization of the structure, according to an embodiment of the invention;

FIG. 11 is a cross-sectional view of the structure and illustrates formation of an inter-layer dielectric, a liner and an upper metal wire, according to an embodiment of the invention;

FIG. 12 is a cross-sectional view of a second structure shown during an intermediate step of fabrication, according to another embodiment of the invention;

FIG. 13 is a cross-sectional view of the second structure and illustrates patterning of a dielectric cap layer, according to an embodiment of the invention;

FIG. 14 is a cross-sectional view of the second structure and illustrates deposition of a first barrier layer, according to an embodiment of the invention;

FIG. 15 is a cross-sectional view of the second structure and illustrates removal of a portion of the first barrier layer, according to an embodiment of the invention;

FIG. 16 is a cross-sectional view of the second structure and illustrates deposition of a second barrier layer, according to an embodiment of the invention;

FIG. 17 is a cross-sectional view of the second structure and illustrates removal of a portion of the second barrier layer, according to an embodiment of the invention;

FIG. 18 is a cross-sectional view of the second structure and illustrates deposition of a conductive material, according to an embodiment of the invention;

FIG. 19 is a cross-sectional view of the second structure and illustrates planarization of the structure, according to an embodiment of the invention; and

FIG. 20 is a cross-sectional view of the second structure and illustrates formation of an inter-layer dielectric, a liner and an upper metal wire, according to an embodiment of the invention.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

As stated above, back end of line (BEOL) is the portion of an integrated circuit where the individual devices (transistors, capacitors, resisters, etc.) get interconnected with one or more metallization layers. The BEOL generally begins above the front-end-of-line region which contains the devices themselves. In general, the BEOL includes contacts, insulating layers (dielectrics), metal levels, and bonding sites for chip-to-package connections and wiring for metal lines. For multi-level interconnection of advanced semiconductor devices, metal via structures are used to enable metal-to-metal contact to the levels below. Via structures typically include both a main conductor material and several suitable nucleation, liner and/or barrier layers. These layers ensure adequate adhesion to the surrounding dielectric as well as good nucleation and growth of the main conductor material. The liner and barrier materials typically exhibit high resistivity, and the presence of such high-resistivity liner and barrier layers in a via structure results in high via resistance which negatively impacts device performance. In addition, the various interfaces formed by these liner and barrier layers can add resistance components to the overall via resistance. There is a need for via structures with reduced via resistance.

The present invention generally relates to semiconductor structures, and more particularly to a via structure with low resistance. The via structure with low resistance is formed with a novel via structure with a widened via bottom. In an embodiment, the via structure has a widened rectangular lower portion. In an alternate embodiment, the via structure has a trapezoid shaped lower portion. In an embodiment, the via structure has sidewall barrier layers and does not have a bottom barrier, such that the via structure is directly connected to a lower metal wire. A via structure may be referred to as a via and also may be referred to as an interconnect structure.

The via structure with a widened via bottom improves performance of devices due to a reduced via resistance. The via structure with a widened via bottom has a reduced via resistance due to the larger bottom interface cross-sectional area. The via structure with a widened via bottom extends scalability of via structures due to an enlarged process window due to the larger bottom interface cross-sectional area between a lower horizontal surface of the via and an upper horizontal surface of a lower metal line below the via. The via structure is a homogeneous interconnect structure embedded in a dielectric layer.

The via structure with a widened via bottom and associated method disclosed herein enables a novel solution for providing a low resistance via structure.

In an embodiment, the via structure has an upper portion and a lower portion. In an embodiment, the via structure has a widened bottom portion. The lower or bottom portion has a width which is wider than a width of a lowermost point of the upper portion.

In an alternate embodiment, the via structure has a trapezoid shaped lower portion. A width of the lowermost point of the bottom portion has a width which is wider than a width of a lowermost point of the upper portion.

In an embodiment, a dielectric cap is formed on a lower metal wire. An inter-layer dielectric (hereinafter “ILD”) is formed and a via opening is etched by removal of a portion of the ILD vertically aligned about the lower metal wire. A portion of the dielectric cap is removed from a lower surface of the via opening, exposing an upper horizontal surface of the lower metal wire.

In an embodiment, a lateral dielectric cap etch, for example by a wet etch, removes an additional portion of the dielectric cap, exposing an additional portion of the upper horizontal surface of the lower metal wire. The additional portion of the dielectric cap which is removed is removed from below a lower horizontal surface of the ILD. A first barrier layer may be conformally formed on horizontal and vertical surfaces of the via opening, on the ILD and on the upper horizontal surface of the lower metal wire. In an embodiment, the first barrier layer is removed from the upper horizontal surface of the lower metal wire. A second barrier layer may be conformally formed on horizontal and vertical surfaces of the via opening, on the first barrier layer and on the upper horizontal surface of the lower metal wire. In an embodiment, the second barrier layer is removed from the upper horizontal surface of the lower metal wire. A via metal fill may be deposited in the via opening, on the second barrier layer and on the upper horizontal surface of the lower metal wire. The resulting via structure is a via structure with a widened bottom section which has a rectangular shape.

In an alternate embodiment, a post tapered dielectric cap etch, for example by a high temperature dry etch, removes an additional portion of the dielectric cap, exposing an additional portion of the upper horizontal surface of the lower metal wire. The additional portion of the dielectric cap which is removed is removed from below a lower horizontal surface of the ILD. A first barrier layer may be conformally formed on horizontal and vertical surfaces of the via opening, on the ILD and on the upper horizontal surface of the lower metal wire. In an embodiment, the first barrier layer is removed from the upper horizontal surface of the lower metal wire. A second barrier layer may be conformally formed on horizontal and vertical surfaces of the via opening, on the first barrier layer and on the upper horizontal surface of the lower metal wire. In an embodiment, the second barrier layer is removed from the upper horizontal surface of the lower metal wire. A via metal fill may be deposited in the via opening, on the second barrier layer and on the upper horizontal surface of the lower metal wire. The resulting via structure is a via structure with a widened bottom section which has a trapezoid shape.

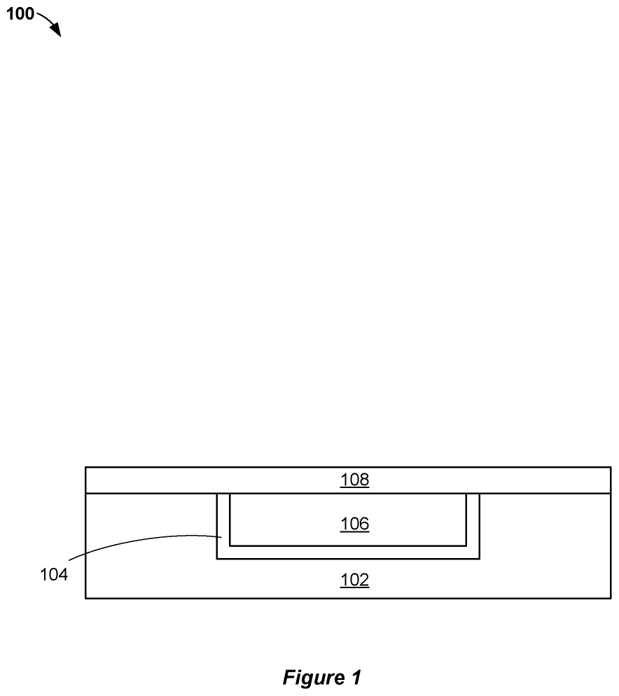

Exemplary embodiments of a via structure with a widened via bottom are described in detail below by referring to the accompanying drawings in FIGS. 1 to 20. Those skilled in the art will readily appreciate that the detailed description given herein with respect to these figures is for explanatory purposes as the invention extends beyond these limited embodiments.

Referring now to FIG. 1, a semiconductor structure 100 (hereinafter “structure”) is shown during an intermediate step of a method of fabricating a via, according to an embodiment of the invention. FIG. 1 is a cross-sectional view of the structure 100. The structure 100 may be formed or provided. The structure 100 may include an inter-layer dielectric (hereinafter “ILD”) 102, a liner 104, a lower metal wire 106 and a dielectric cap 108.

The structure 100 may include several back end of line (“BEOL”) layers on a substrate (not shown). In general, the back end of line (BEOL) is the portion of integrated circuit where the individual devices (transistors, capacitors, resistors, etc.) are interconnected with wiring on the wafer. The substrate (not shown) may include a bulk semiconductor or a layered semiconductor such as Si/SiGe, a silicon-on-insulator (SOI), or a SiGe-on-insulator (SGOI). Bulk substrate materials may include undoped Si, n-doped Si, p-doped Si, single crystal Si, polycrystalline Si, amorphous Si, Ge, SiGe, SiC, SiGeC, Ga, GaAs, InAs, InP and all other III/V or II/VI compound semiconductors. In other embodiments, the substrate (not shown) may represent a device region, such as the front-end-of-line, or a prior metallization level in the back-end-of-line, such as Mx_. In some cases, the substrate (not shown) may generally be referred to as a wafer.

The ILD 102 may be formed by depositing or growing a dielectric material on the BEOL layers, followed by a chemical mechanical polishing (CMP) or etch steps. The ILD 102 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the ILD 102 may include one or more layers. In an embodiment, the ILD 102 may include any dielectric material such as silicon oxide (SiOx), silicon nitride (SiNx), silicon boron carbonitride (SiBCN), NBLoK, a low-k dielectric material (with k<4.0), including but not limited to, silicon oxide, spin-on-glass, a flowable oxide, a high-density plasma oxide, borophosphosilicate glass (BPSG), or any combination thereof or any other suitable dielectric material.

The lower metal wire 106 may be formed by first patterning a trench (not shown) into the ILD 102, lining the trench with the liner 104, and filling the trench.

The liner 104 separates the conductive interconnect material of the lower metal wire 106 from the ILD 102. The liner 104 may be composed of, for example, tantalum nitride (TaN), tantalum (Ta), titanium (Ti), titanium nitride (TiN), or a combination thereof. The liner 104 may be deposited utilizing a conventional deposition process such as, for example, CVD, plasma enhanced chemical vapor deposition (PECVD), PVD or ALD. The liner 104 may be 5 nm thick, although a thickness less than or greater than 5 nm may be acceptable. The liner 104 surrounds a lower horizontal surface and a vertical side surface of the lower metal wire 106.

In an embodiment, the lower metal wire 106 is formed from a conductive material layer which is blanket deposited on top of the structure 100, and directly on a top surface of the liner 104, filling the trench. The conductive material layer may include materials such as, for example copper (Cu), ruthenium (Ru), cobalt (Co), tungsten (W). The conductive material can be formed by for example, chemical vapor deposition (CVD), physical vapor deposition (PVD), and atomic layer deposition (ALD) or a combination thereof. The lower metal wire 106 is formed by damascene, or patterned from the conductive material layer, using known patterning and etching techniques. There may be any number of openings in the ILD 102, each filled with the liner 104 and the lower metal wire 106, on the structure 100.

A planarization process, such as, for example, chemical mechanical polishing (CMP), may be done to remove excess material from a top surface of the structure 100 such that upper horizontal surfaces of the lower metal wire 106, the liner 104 and the ILD 102 are coplanar.

In an embodiment, the lower metal wire 106 may have a thickness ranging from about 10 nm to about 100 nm, although a thickness less than 10 nm and greater than 100 nm may be acceptable.

The dielectric cap 108 may be formed as described for the ILD 102. In an embodiment, the dielectric cap 108 may include any dielectric material such as silicon nitride (SiNx), silicon carbonitride (SiNC), a low-k dielectric material (with k<4.0), or any combination thereof or any other suitable dielectric material.

In an embodiment, the dielectric cap 108 may include a different dielectric material than the ILD 102. In an alternate embodiment, the dielectric cap 108 may include the same or similar dielectric material as the ILD 102.

The dielectric cap 108 may have a typical thickness ranging from about 10 nm to about 100 nm and ranges there between, although a thickness less than 10 nm or greater than 100 nm are explicitly contemplated.

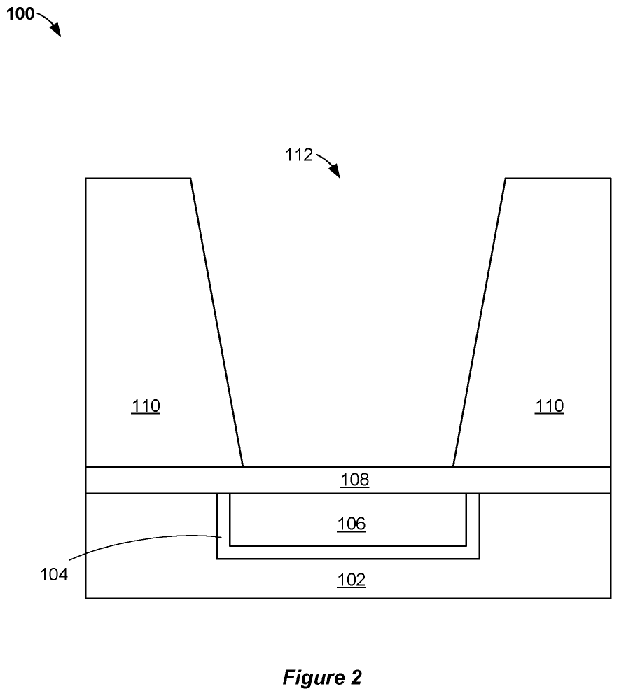

Referring now to FIG. 2, the structure 100 is shown according to an embodiment of the invention. An inter-layer dielectric (hereinafter “ILD”) 110 may be formed. Portions of the ILD 110 may be removed, forming a via opening 112.

The ILD 110 may be formed directly on the dielectric cap 108. The ILD 110 may be formed of a material and as described for the ILD 102. In an embodiment, the ILD 110 may include any dielectric material such as organosilicate glass (SiCOH), silicon dioxide (SiO₂), a low-k dielectric material (with k<4.0), or any combination thereof or any other suitable dielectric material.

In an embodiment, the ILD 110 may include a different dielectric material than the dielectric cap 108 to allow for selective removal. In an alternate embodiment, the ILD 110 may include the same or similar dielectric material as the dielectric cap 108.

The ILD 110 may have a typical thickness ranging from about 30 nm to about 100 nm, although a thickness less than 30 nm or greater than 100 nm are explicitly contemplated.

The via opening 112 may be formed by methods known in the arts by selective removal of a portion of the ILD 110 exposing an upper horizontal surface of the dielectric cap 108. The via opening 112 may be vertically aligned with the lower metal wire 106. The via opening 112 may subsequently be formed into a via connected the lower metal wire 106 to other objects in the structure 100. There may be any number of via openings 112 in the ILD 110.

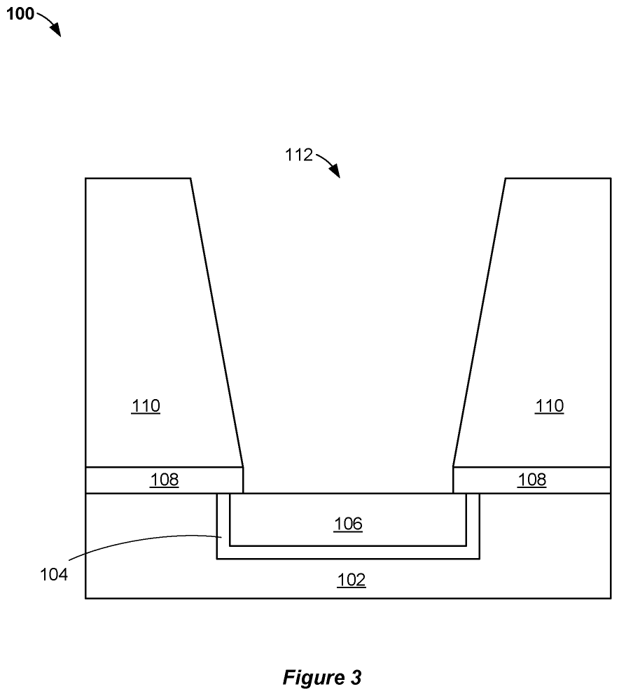

Referring now to FIG. 3, the structure 100 is shown according to an embodiment of the invention. Portions of the dielectric cap 108 may be removed, increasing an area of the via opening 112.

Exposed portions of the dielectric cap 108 may be selectively removed by methods known in the arts, selective to the ILD 110 and the lower metal wire 106, exposing an upper horizontal surface of the lower metal wire 106.

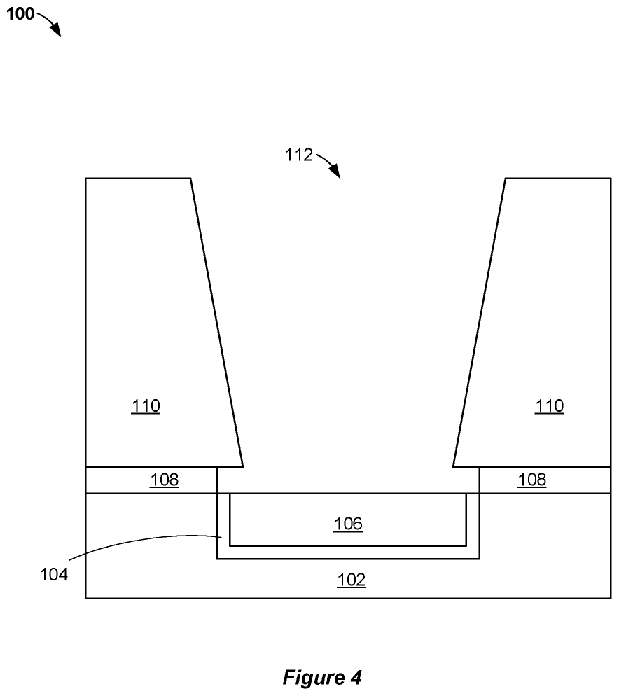

Referring now to FIG. 4, the structure 100 is shown according to an embodiment of the invention. Additional portions of the dielectric cap 108 may be removed, further increasing an area of the via opening 112.

The additional portions of the dielectric cap 108 may be removed, for example, by a wet etch, or other method. The additional portions of the dielectric cap 108 may be removed selective to the ILD 110 and the lower metal wire 106, exposing an upper horizontal surface of the lower metal wire 106 and the liner 104. The additional portions of the dielectric cap 108 may be removed from below a lower horizontal surface of the ILD 110. A portion of the ILD 110 may overhang a portion of the via opening 112.

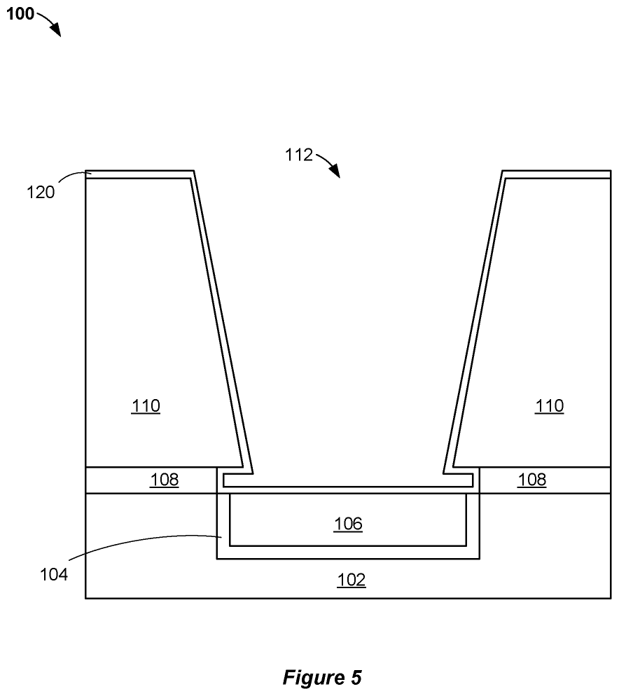

Referring now to FIG. 5, the structure 100 is shown according to an embodiment of the invention. A first barrier layer 120 may be formed.

The first barrier layer 120, or nucleation layer, is formed by conformally depositing a barrier material over the structure 100 according to known techniques. Specifically, the barrier material is conformally deposited on a top, on sidewalls and on an exposed lower horizontal surface of the ILD 110, exposed sidewalls of the dielectric cap 108, exposed upper surfaces of the liner 104 and exposed surfaces of the lower metal wire 106, as illustrated. As used herein, “conformal” is meant that a material layer has a continuous thickness, or substantially continuous thickness. For example, a continuous or a same thickness generally means a first thickness as measured from a bottom surface to a topmost surface that is the same as a second thickness as measured from an inner sidewall surface to an outer sidewall surface.

As well known by a person skilled in the art, the first barrier layer 120 is typically applied to create a diffusion barrier between sidewall portions of the surrounding dielectrics (ILD 110, dielectric cap 108). As such, the first barrier layer 120 would be designed to prevent diffusion of any subsequently deposited conductive material into the surrounding dielectrics (ILD 110, dielectric cap108). According to embodiments of the present invention, the first barrier layer 120 is composed of any known suitable barrier materials, for example, metal nitrides. In an embodiment, the first barrier layer 120 includes tantalum nitride (TaN), titanium nitride (TiN), tungsten nitride (WN), boron carbon doped tungsten (WBC), or some combination thereof. In an embodiment, the first barrier layer 120 includes multiple layers, for example, a tantalum layer and a tantalum nitride layer. In a preferred embodiment, the first barrier layer 120 includes a single layer of titanium nitride (TiN).

In an embodiment, the first barrier layer 120 can be formed using a deposition technique including, for example, atomic layer deposition (ALD), chemical vapor deposition (CVD), plasma enhanced chemical vapor deposition (PECVD), physical vapor deposition (PVD), evaporation, spin-on coating, or sputtering.

In general, the first barrier layer 120 may have a thickness sufficient to achieve desired barrier properties as is well known to persons having skill in the art. For example, the first barrier layer 120 may have a typical thickness ranging from about 1 nm to about 4, although thicknesses less than 1 nm or greater than 4 nm are explicitly contemplated.

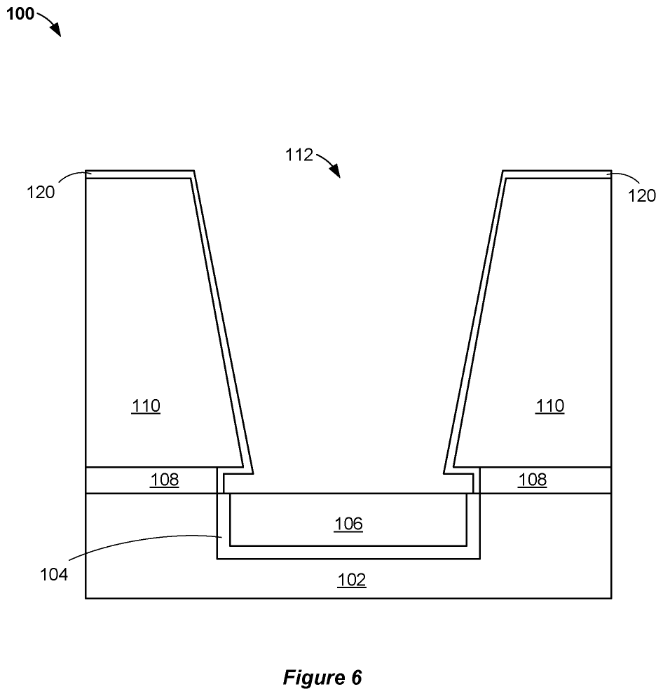

Referring now to FIG. 6, the structure 100 is shown according to an embodiment of this invention. Portions of the first barrier layer 120 may be removed.

An etching technique is applied to generally remove portions of the first barrier layer 120 according to known techniques. Specifically, a suitable etching technique is used to remove portions of the first barrier layer 120 and expose an upper horizontal surface of the liner 104 and an upper horizontal surface of the lower metal wire 106.

The first barrier layer 120 may remain on an upper horizontal surface, a vertical side surface and a lower horizontal surface of the ILD 110, on a vertical side surface of the dielectric cap 108 and on an upper horizontal surface of the liner 104.

In an alternate embodiment, the first barrier layer 120 may remain on the upper horizontal surface of the liner 104 and the upper horizontal surface of the lower metal wire 106.

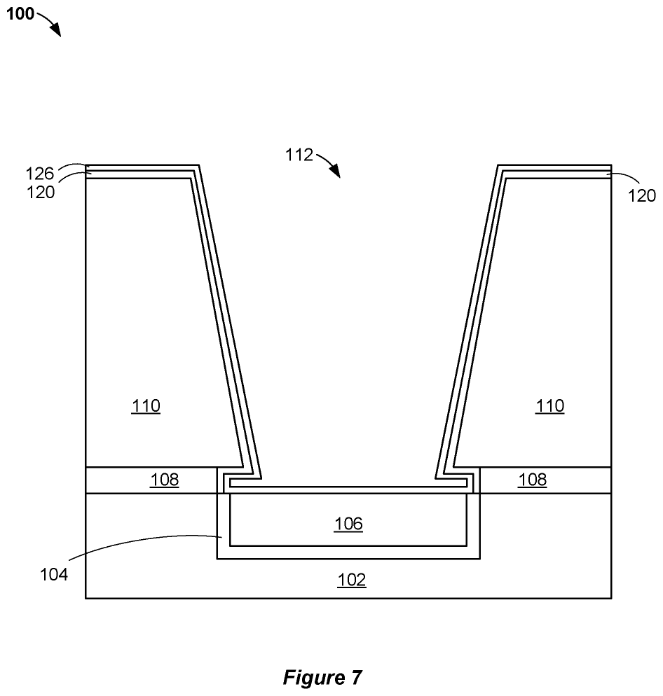

Referring now to FIG. 7, the structure 100 is shown according to an embodiment of the invention. A second barrier layer 126 may be formed.

The second barrier layer 126, or nucleation layer, is formed by conformally depositing a barrier material over the structure 100 according to known techniques. Specifically, the barrier material is conformally deposited on exposed surfaces of the first barrier layer 120, on the upper horizontal surface of the liner 104 and the upper horizontal surface of the lower metal wire 106, as illustrated.

In the alternate embodiment where the first barrier layer 120 remains on the upper horizontal surface of the liner 104, the second barrier layer 126 may be formed on the first barrier layer 120 which is on the upper horizontal surface of the liner 104 and the upper horizontal surface of the lower metal wire 106.

The second barrier layer 126 may typically be applied to create a diffusion break between sidewall portions of subsequently formed dielectrics. As such, the second barrier layer 126 would be designed to prevent diffusion of the conductive material of individual interconnect structures into adjacent dielectric structures. According to embodiments of the present invention the second barrier layer 126 is composed of any known suitable barrier materials, for example, metal nitrides. In an embodiment, the second barrier layer 126 is titanium nitride (TiN), tungsten nitride (WN), tantalum nitride (TaN) boron carbon doped tungsten (WBC), or some combination thereof. In an embodiment, the second barrier layer 126 includes multiple layers for example a tantalum layer and a tantalum nitride layer. In another embodiment, the second barrier layer 126 includes a single layer of tungsten nitride (WN). In yet another embodiment, the first barrier layer 120 includes a single layer of titanium tungsten nitride (TiWN). Further, the second barrier layer 126 may be the same or different composition as the first barrier layer 120. In all cases, the barrier layers (120, 126) would preferably be chosen based on the specific surrounding materials of the ILD 102, the ILD 110, the dielectric cap 108 and conductive material to be used to fill the via by filling the via opening 112. In a preferred embodiment, the first barrier layer 120 includes a single layer of titanium nitride (TiN). In a preferred embodiment, the second barrier layer 126 includes a single layer of titanium nitride tungsten nitride (TiWN).

In an embodiment, the second barrier layer 126 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

In general, the second barrier layer 126 may have a thickness sufficient to achieve desired barrier properties as is well known to persons having skill in the art. For example, the second barrier layer 126 may have a typical thickness ranging from about 1 nm to about 4 nm, although a thickness less than 1 nm or greater than 4 nm are explicitly contemplated.

In an embodiment, the first barrier layer 120 may include titanium nitride (TiN) and the second barrier layer 126 may include tungsten nitride (WN).

The purpose of the first barrier layer 120 is to ensure adequate adhesion to the surrounding ILD 110 and the dielectric cap 108. The purpose of the second barrier layer 126 is to ensure adequate adhesion to subsequently deposited conductive material. The purpose of including both the first barrier layer 120 and the second barrier layer 126 is to provide tailored materials which enable adequate adhesion to both the dielectric and the conductive material, while also preventing diffusion of the conductive material into the dielectric.

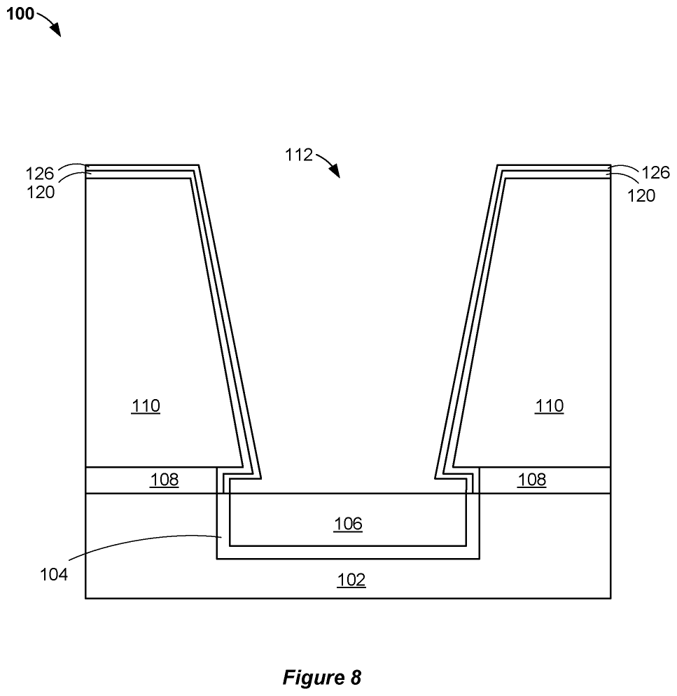

Referring now to FIG. 8, the structure 100 is shown according to an embodiment of the invention. A portion of the second barrier layer 126 may be removed.

An etching technique is applied to remove horizontal portions of the second barrier layer 126 in the via opening 112, according to known techniques. Specifically, one or more dry etching techniques are used to remove horizontal portions of the second barrier layer 126, as illustrated. Suitable dry etching techniques may include, but are not limited to: reactive ion etching (RIE), ion beam etching, plasma etching, or laser ablation. In all cases, the dry etching technique shall cause remaining portions of the second barrier layer 126 to remain on the sidewalls of the via opening 112. The second barrier layer 126 may be removed from an upper horizontal surface of the ILD 110 in the via opening 112 and expose an upper horizontal surface of the liner 104 and an upper horizontal surface of the lower metal wire 106.

The second barrier layer 126 may remain on an upper horizontal surface, a vertical side surface and a lower horizontal surface of the first barrier layer 120 surrounding the ILD 110, on a vertical side surface of the first barrier layer 120 surrounding the dielectric cap 108 and on an upper horizontal surface of the liner 104.

In an alternate embodiment, the second barrier layer 126 may not have portions removed, and may remain on the upper horizontal surface of the liner 104 and the upper horizontal surface of the lower metal wire 106. In a further embodiment, the second barrier layer 126 may not have portions removed, and may remain on the upper horizontal surface of the first barrier layer 120 covering the liner 104 and the lower metal wire 106.

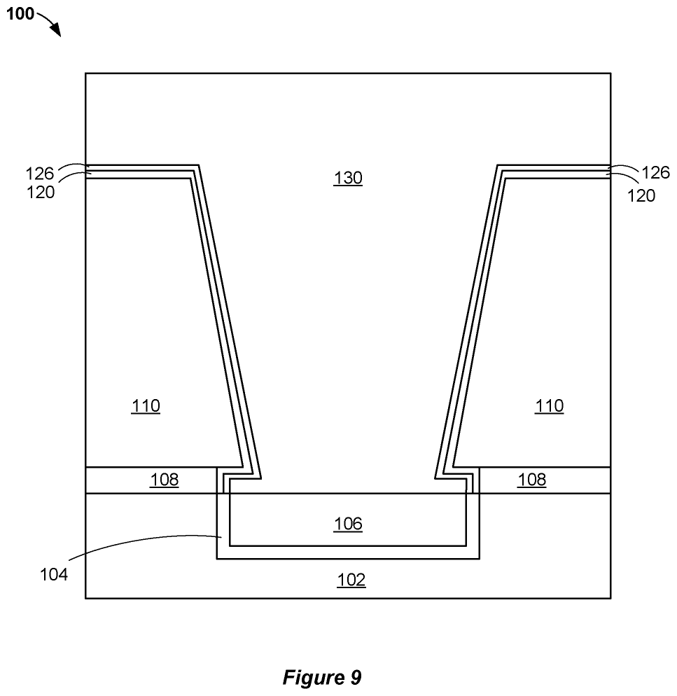

Referring now to FIG. 9, the structure 100 is shown according to an embodiment of the invention. Conductive material for the via 130 may be deposited.

The conductive material for the via 130 is blanket deposited on the structure 100 filling the via opening 112 according to known techniques. More specifically, according to an embodiment, the conductive material for the via 130 is blanket deposited directly on exposed surfaces of the second barrier layer 126, the liner 104 and the lower metal wire 106, as illustrated.

According to embodiments of the present invention the conductive material for the via 130 may include any suitable conductive interconnect materials such as tungsten (W), molybdenum (Mo), rhodium (Rh), iridium (Ir), copper (Cu), or alloys or combinations thereof.

The conductive material for the via 130 may be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

In general, deposition of the conductive material for the via 130 continues until the via opening 112 is completely filled and well in excess of uppermost surface of the structure 100, as illustrated. For example, the conductive material for the via 130 may have a typical thickness ranging from about 60 nm to about 300 nm and ranges there between, although a thickness less than 60 nm and greater than 300 nm are explicitly contemplated.

Forming the via 130 which directly contacts the lower metal wire 106 without the fist barrier layer 120 nor the second barrier layer 126 between the via 130 and the lower metal wire 106 forms a via 130 with a lower resistance than a via 130 which has the first barrier layer 120 and/or the second barrier layer 126 between the via 130 and the lower metal wire 106. The via 130 may be homogeneous and formed with one deposition of the conductive material for the via 130 for an entire height of the via 130.

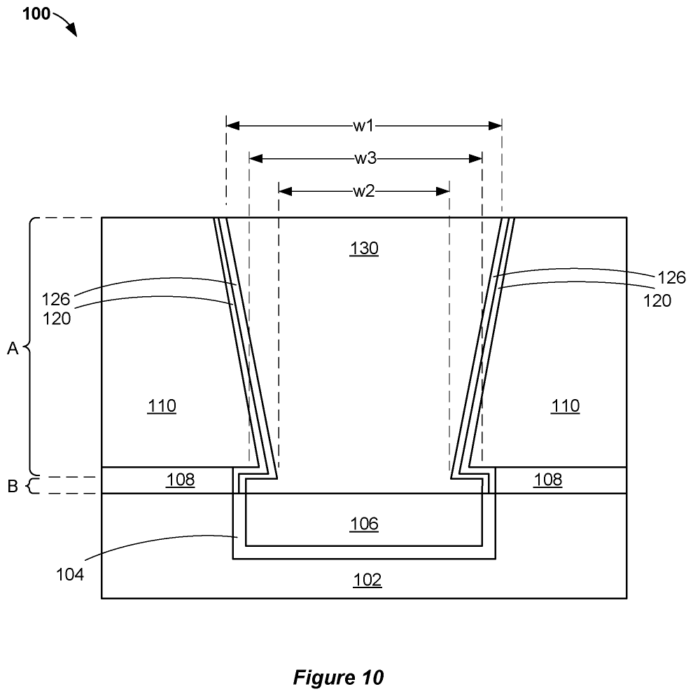

Referring now to FIG. 10, the structure 100 is shown according to an embodiment of the invention. Portions of the via 130, portions of the ILD 110, portions of the first barrier layer 120 and portions of the second barrier layer 126 may be removed.

A planarization process, such as, for example, chemical mechanical polishing (CMP), may be done to remove excess material from a top surface of the structure 100 such that upper horizontal surfaces of the via 130, the ILD 110, the first barrier layer 120 and the second barrier layer 126 are coplanar.

The via 130 has an upper region A and a lower region B. In the upper region A of the via 130, a width of the via 130, w1, at an upper horizontal surface of the via 130 is greater than a width of the via 130 at a lower horizontal surface, w2, of the upper region A. The ILD 110 overhangs the dielectric cap 108. In the lower region B of the via 130, a width of the via 130, w3, is greater than the width of the lower horizontal surface, w2, of the upper region A.

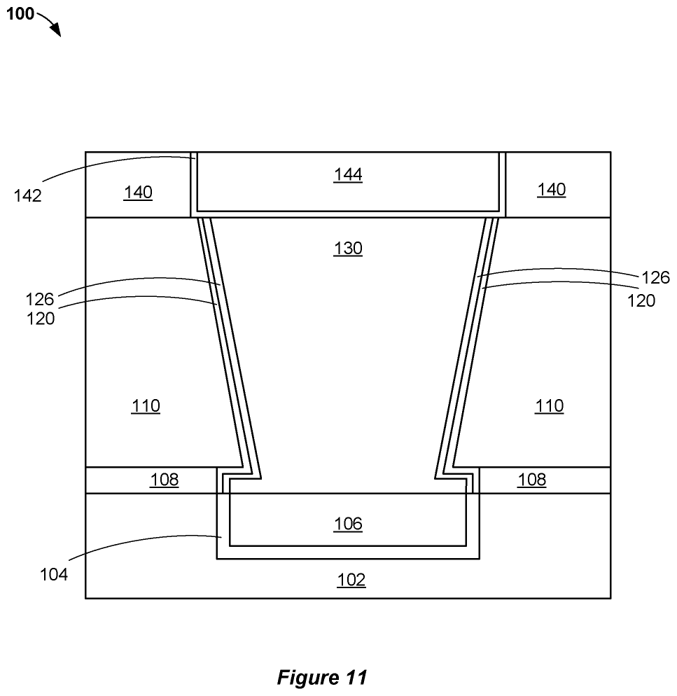

Referring now to FIG. 11, the structure 100 is shown according to an embodiment of the invention. An inter-layer dielectric (hereinafter “ILD”) 140 may be formed. A liner 142 may be formed. An upper metal wire 144 may be formed.

The ILD 140 may be conformally formed on the ILD 110, the first barrier layer 120, the second barrier layer 126 and the via 130. The ILD 140 may be formed of a material and as described for the ILD 102. In an embodiment, the ILD 140 may include any dielectric material such as organosilicate glass (SiCOH), silicon dioxide (SiO₂), a low-k dielectric material (with k<4.0), or any combination thereof or any other suitable dielectric material. A planarization process, such as, for example, chemical mechanical polishing (CMP), may be done to remove excess material from a top surface of the structure 100 to form a coplanar upper horizontal surfaces of the ILD 140.

The upper metal wire 144 may be formed by first patterning a trench (not shown) vertically aligned above the via 130 into the ILD 140, lining the trench with the liner 142, and filling the trench.

The liner 142 separates the conductive interconnect material of the upper metal wire 144 from the ILD 140. The liner 142 be formed as described for the liner 104. The liner 142 surrounds a lower horizontal surface and a vertical side surface of the upper metal wire 144.

In an embodiment, the upper metal wire 144 is formed from a conductive material layer which is blanket deposited on top of the structure 100, and directly on a top surface of the liner 142, filling the trench. The upper metal wire 144 may be formed as described for the lower metal wire 106.

A planarization process, such as, for example, chemical mechanical polishing (CMP), may be done to remove excess material from a top surface of the structure 100 such that upper horizontal surfaces of the upper metal wire 144, the liner 142 and the ILD 110 are coplanar.

The structure 100 may include any number of lower metal wire 106, via 130 and upper metal wire 144.

The via 130 with a widened via bottom improves performance of devices due to a reduced via resistance and extends scalability of via structures due to enlarged process window for low via resistance.

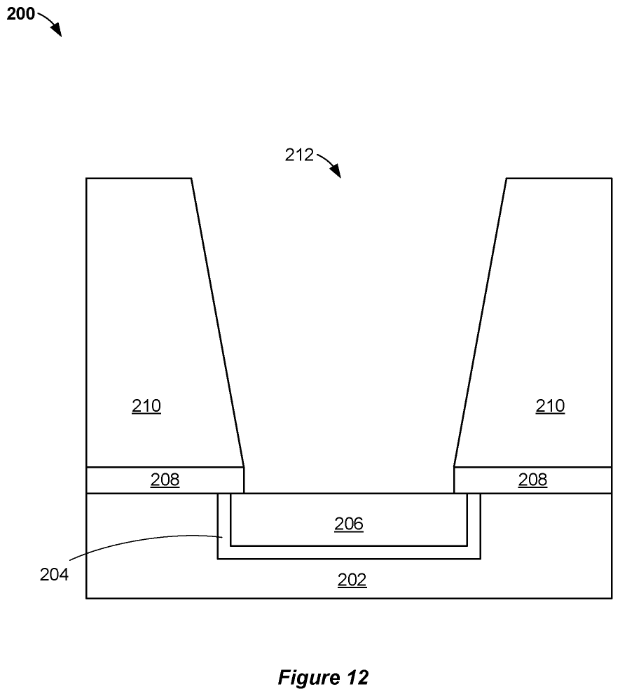

Referring now to FIG. 12, a semiconductor structure 200 (hereinafter “structure”) is shown during an intermediate step of a method of fabricating a via, according to an embodiment of the invention. FIG. 12 is a cross-sectional view of the structure 200. The structure 200 may be formed or provided. The structure 200 may include an inter-layer dielectric (hereinafter “ILD”) 202, a liner 204, a lower metal wire 206, a dielectric cap 208, an inter-layer dielectric (hereinafter “ILD”) 210 and a via opening 212.

The structure 200 is an alternate embodiment of the invention. Structures with similar names in the FIG. 200 may be formed as described for the FIG. 100.

The structure 200 may be formed as described for the structure 100 shown in FIG. 3.

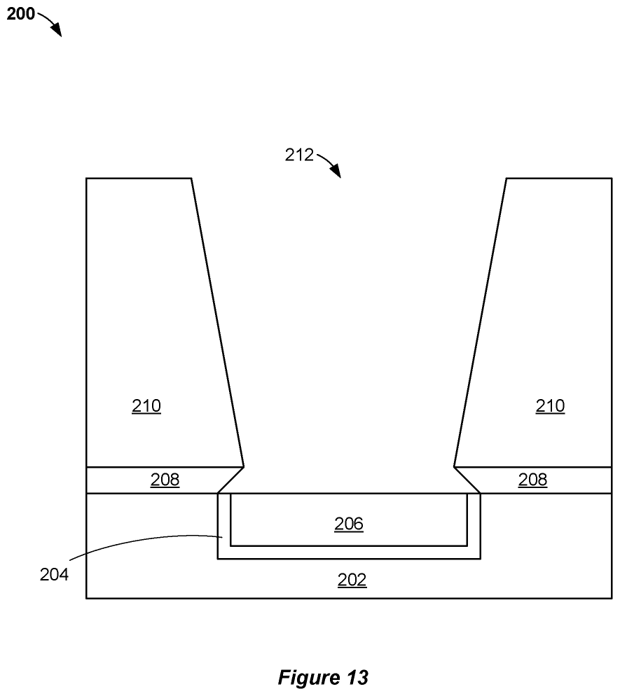

Referring now to FIG. 13, the structure 200 is shown according to an embodiment of the invention. Additional portions of the dielectric cap 108 may be removed, further increasing an area of the via opening 212.

The structure 200 may then be subject to a post tapered dielectric cap etch to the dielectric cap 208 to further increase the opening 212. The additional portions of the dielectric cap 208 may be removed, for example, by a wet etch, or other method. The additional portions of the dielectric cap 208 may be removed selective to the ILD 210, the liner 204 and the lower metal wire 206, exposing an upper horizontal surface of the lower metal wire 206 and the liner 204. The structure 200 has a portion of the dielectric cap 108 removed and a vertical side surface of the dielectric cap 208 is angled.

This is in comparison to the structure 100, as shown in FIG. 4. The structure 100 in FIG. 4 has a portion of the dielectric cap 108 removed and a vertical side surface of the dielectric cap 108 is perpendicular to a horizontal upper surface of the lower metal wire 106. In the structure 100, the ILD 110 overhangs the dielectric cap 108, with a portion of the lower horizontal surface of the ILD 110 exposed.

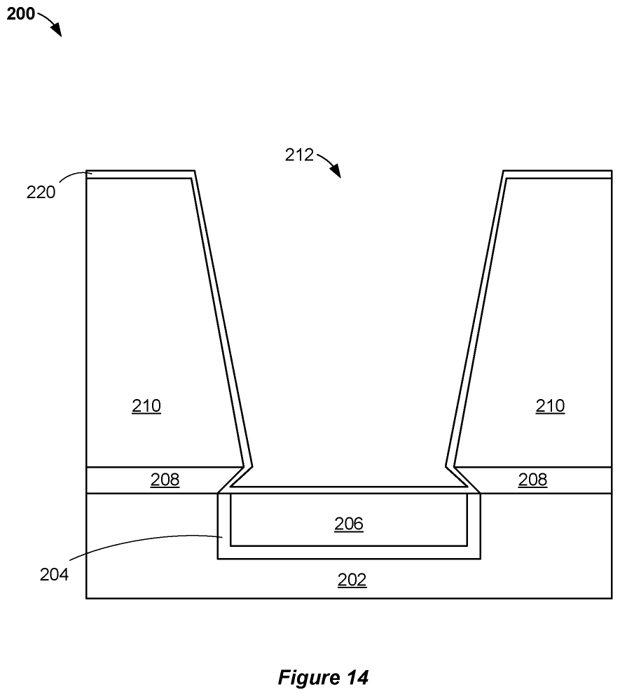

Referring now to FIG. 14, the structure 200 is shown according to an embodiment of the invention. A first barrier layer 220 may be formed.

The first barrier layer 220, may be formed as described for the first barrier layer 120, conformally deposited on a top, on sidewalls and on an exposed lower horizontal surface of the ILD 210, exposed sidewalls of the dielectric cap 208, exposed upper surfaces of the liner 204 and exposed surfaces of the lower metal wire 206, as illustrated.

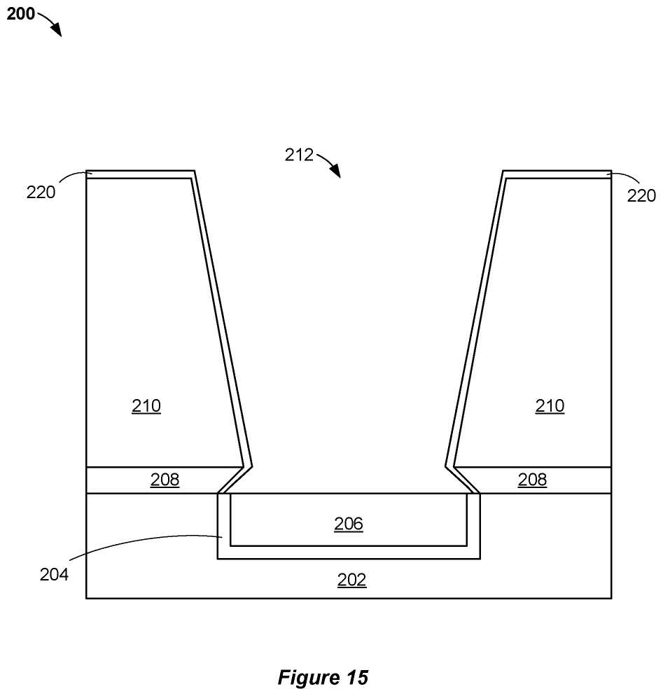

Referring now to FIG. 15, the structure 200 is shown according to an embodiment of this invention. Portions of the first barrier layer 220 may be removed.

An etching technique is applied to generally remove portions of the first barrier layer 220 according to known techniques. Specifically, a suitable etching technique is used to remove portions of the first barrier layer 220 and expose an upper horizontal surface of the liner 204 and an upper horizontal surface of the lower metal wire 206.

The first barrier layer 220 may remain on an upper horizontal surface, a vertical side surface and a lower horizontal surface of the ILD 210, on a vertical side surface of the dielectric cap 208 and on an upper horizontal surface of the liner 204.

In an alternate embodiment, the first barrier layer 220 may remain on the upper horizontal surface of the liner 204 and the upper horizontal surface of the lower metal wire 206.

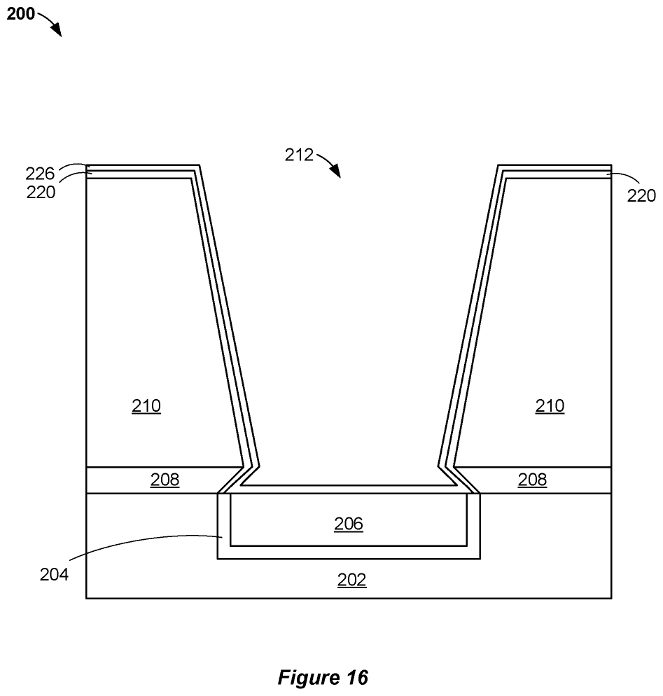

Referring now to FIG. 16, the structure 100 is shown according to an embodiment of the invention. A second barrier layer 226 may be formed.

The second barrier layer 226, or nucleation layer may be formed as described for the second barrier layer 126. The barrier material is conformally deposited on exposed surfaces of the first barrier layer 220, on the upper horizontal surface of the liner 204 and the upper horizontal surface of the lower metal wire 206, as illustrated.

In the alternate embodiment where the first barrier layer 220 does not have a portion removed, the second barrier layer 226 may be formed on the first barrier layer 220 which is on the upper horizontal surface of the liner 204 and the upper horizontal surface of the lower metal wire 206.

The second barrier layer 226 may typically be applied to create a diffusion break between sidewall portions of subsequently formed dielectrics. As such, the second barrier layer 226 would be designed to prevent diffusion of the conductive material of individual interconnect structures into the subsequently formed dielectrics. The second barrier layer 126 may be the same or different composition as the first barrier layer 220. In all cases, the barrier layers (220, 226) would preferably be chosen based on the specific surrounding materials of the ILD 202, ILD 210, dielectric cap 208 and conductive material to be used to fill the via by filling the opening 212. In a preferred embodiment, the first barrier layer 220 includes a single layer of titanium nitride (TiN). In a preferred embodiment, the second barrier layer 226 includes a single layer of titanium nitride tungsten nitride (TiWN).

The purpose of the first barrier layer 220 is to ensure adequate adhesion to the surrounding ILD. The purpose of the second barrier layer 226 is to ensure adequate adhesion to the subsequently deposited conductive material. The purpose of including both the first barrier layer 220 and the second barrier layer 226 is to provide tailored materials which enable adequate adhesion to both the dielectric and the conductive material, while also preventing diffusion of the conductive material into the dielectric.

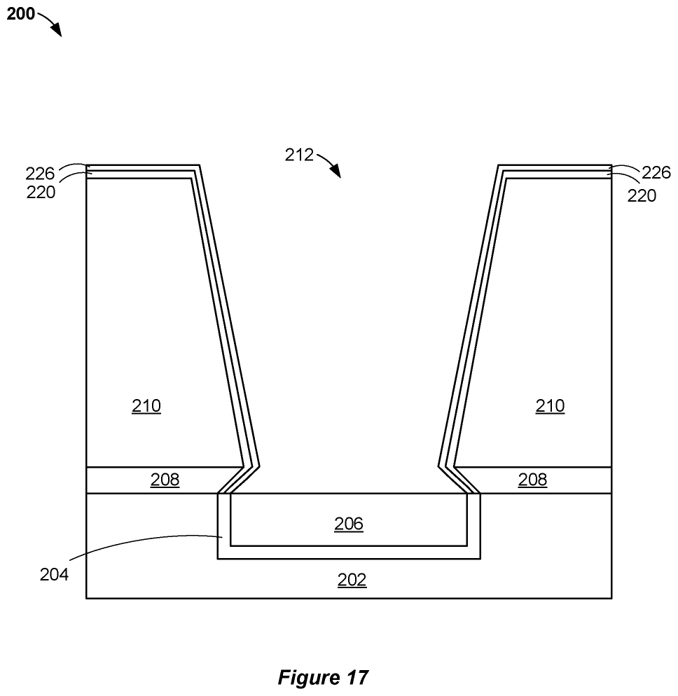

Referring now to FIG. 17, the structure 200 is shown according to an embodiment of the invention. A portion of the second barrier layer 226 may be removed.

An etching technique is applied to remove horizontal portions of the second barrier layer 226 in the opening 212, according to known techniques. Specifically, one or more dry etching techniques are used to remove horizontal portions of the second barrier layer 226, as illustrated. Suitable dry etching techniques may include, but are not limited to: reactive ion etching (RIE), ion beam etching, plasma etching, or laser ablation. In all cases, the dry etching technique shall cause remaining portions of the second barrier layer 226 to remain on the sidewalls of the opening 212. The second barrier layer 226 may be removed from an upper horizontal surface of the ILD 210 in the via opening 212 and expose an upper horizontal surface of the liner 204 and an upper horizontal surface of the lower metal wire 206.

The second barrier layer 226 may remain on an upper horizontal surface, a vertical side surface of the first barrier layer 220 surrounding the ILD 210, on a vertical side surface of the first barrier layer 220 surrounding the dielectric cap 208 and on an upper horizontal surface of the liner 204.

In an alternate embodiment, the second barrier layer 226 may not have portions removed, and may remain on the upper horizontal surface of the liner 204 and the upper horizontal surface of the lower metal wire 206. In a further embodiment, the second barrier layer 226 may not have portions removed, and may remain on the upper horizontal surface of the first barrier layer 220 covering the liner 204 and the lower metal wire 206.

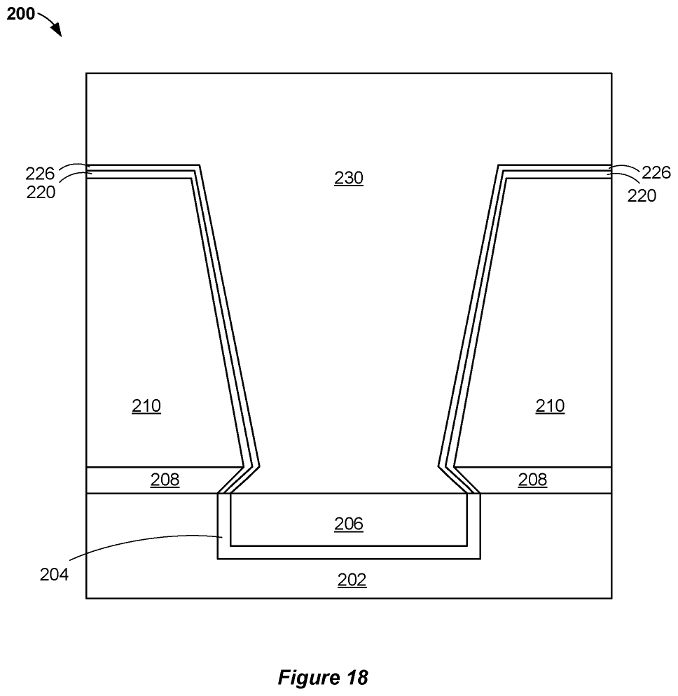

Referring now to FIG. 18, the structure 200 is shown according to an embodiment of the invention. Conductive material for the via 230 may be deposited.

Conductive material for the via 230 is blanket deposited on the structure 100 filling the via opening 212 according to known techniques. More specifically, according to an embodiment, the conductive material for the via 230 is blanket deposited directly on exposed surfaces of the second barrier layer 226, the liner 204 and the lower metal wire 206, as illustrated.

According to embodiments of the present invention the conductive material for the via 230 may include any suitable conductive interconnect materials such as tungsten (W), molybdenum (Mo), rhodium (Rh), iridium (Ir), copper (Cu), or alloys or combinations thereof.

The conductive material for the via 230 may be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

In general, deposition of the conductive material for the via 230 continues until the via opening 212 is completely filled and well in excess of uppermost surface of the structure 200, as illustrated. For example, the conductive material for the via 230 may have a typical thickness ranging from about 60 nm to about 300 nm and ranges there between, although a thickness less than 60 nm and greater than 300 nm are explicitly contemplated. The via 130 may be homogeneous and formed with one deposition of the conductive material for the via 130 for an entire height of the via 130.

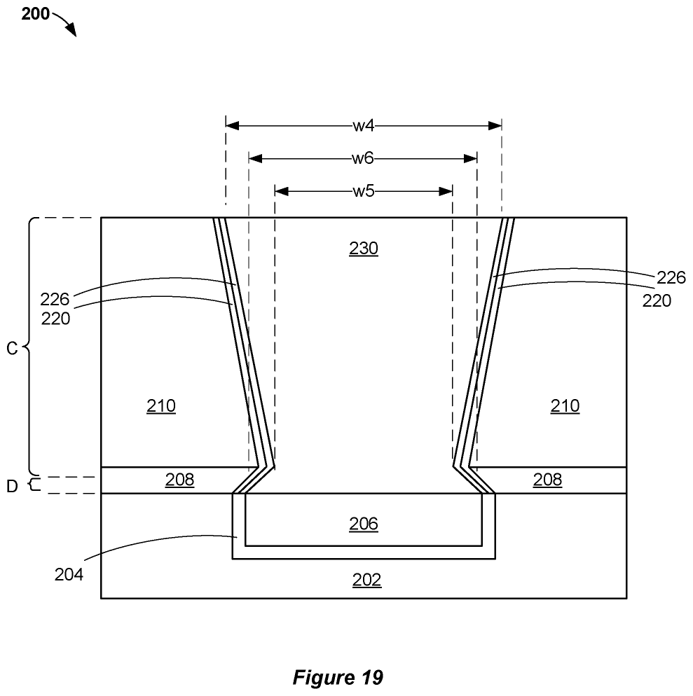

Referring now to FIG. 19, the structure 200 is shown according to an embodiment of the invention. Portions of the via 230, portions of the ILD 210, portions of the first barrier layer 220 and portions of the second barrier layer 226 may be removed.

A planarization process, such as, for example, chemical mechanical polishing (CMP), may be done to remove excess material from a top surface of the structure 200 such that upper horizontal surfaces of the via 230, the ILD 210, the first barrier layer 220 and the second barrier layer 226 are coplanar.

The via 230 has an upper region C and a lower region D. In the upper region C of the via 230, a width of the via 230, w4, at an upper horizontal surface of the via 230 is greater than a width of the via 230 at a lower horizontal surface, w5, of the upper region C. The ILD 210 overhangs the dielectric cap 208. In the lower region D of the via 230, at an upper horizontal surface of the lower region D of the via 230 also has a width of w5. At a lower horizontal surface of the lower region D of the via 230, a width of the via 230 is w6, which is greater than the width of the lower horizontal surface, w5, of the upper region C.

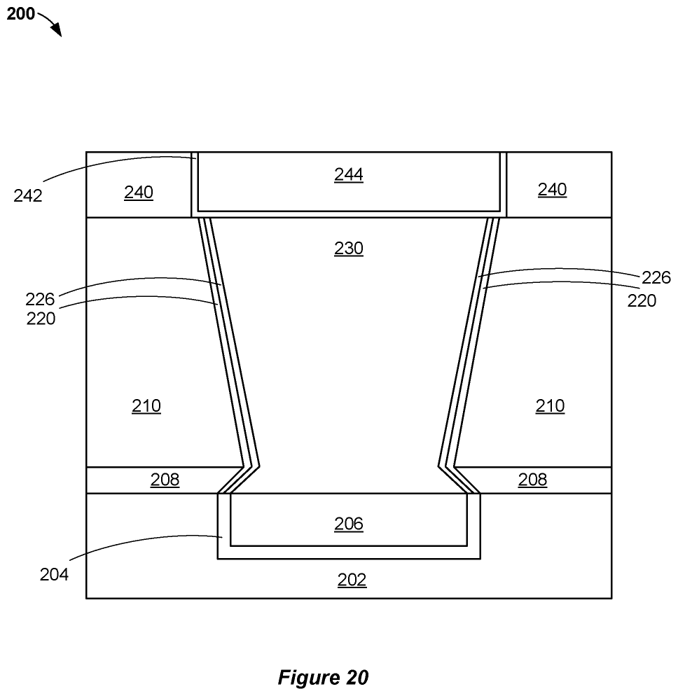

Referring now to FIG. 20, the structure 200 is shown according to an embodiment of the invention. An inter-layer dielectric (hereinafter “ILD”) 240 may be formed. A liner 242 may be formed. An upper metal wire 244 may be formed.

The ILD 240 may be formed on the ILD 210, the first barrier layer 220, the second barrier layer 226 and the via 230. The ILD 240 may be formed of a material and as described for the ILD 102. In an embodiment, the ILD 240 may include any dielectric material such as organosilicate glass (SiCOH), silicon dioxide (SiO₂), a low-k dielectric material (with k<4.0), or any combination thereof or any other suitable dielectric material.

The upper metal wire 244 may be formed by first patterning a trench (not shown) vertically aligned above the via 230 into the ILD 240, lining the trench with the liner 242, and filling the trench.

The liner 242 separates the conductive interconnect material of the upper metal wire 244 from the ILD 240. The liner 242 may be formed as described for the liner 204. The liner 242 surrounds a lower horizontal surface and a vertical side surface of the upper metal wire 244.

In an embodiment, the upper metal wire 244 is formed from a conductive material layer which is blanket deposited on top of the structure 100, and directly on a top surface of the liner 242, filling the trench. The upper metal wire 244 may be formed as described for the lower metal wire 206.

A planarization process, such as, for example, chemical mechanical polishing (CMP), may be done to remove excess material from a top surface of the structure 200 such that upper horizontal surfaces of the upper metal wire 244, the liner 242 and the ILD 210 are coplanar.

The structure 200 may include any number of lower metal wire 206, via 230 and upper metal wire 244.

The via 130 has an upper region A and a lower region B. In the upper region A of the via 130, a width of the via 130, w1, at an upper horizontal surface of the via 130 is greater than a width of the via 130 at a lower horizontal surface, w2, of the upper region A. The ILD 110 overhangs the dielectric cap 108. In the lower region B of the via 130, a width of the via 130, w3, is greater than the width of the lower horizontal surface, w2, of the upper region A.

The via 230 with a widened via bottom improves performance of devices due to a reduced via resistance and extends scalability of via structures due to enlarged process window for low via resistance.

An embodiment of the present invention includes a semiconductor structure including a homogeneous interconnect structure embedded in a dielectric layer, where the homogeneous interconnect structure includes an upper region vertically aligned above a lower region, the first region includes a first width at an upper horizontal surface of the upper region and a second width at a lower horizontal surface of the upper region, where the first width is greater than the second width, and the lower region includes a third width, where the third width is greater than the second width. An embodiment further including a first barrier layer separating the homogeneous interconnect structure from the dielectric layer. An embodiment further including a barrier layer separating the homogeneous interconnect structure from the dielectric layer, where the barrier layer includes at least two different materials. An embodiment where the lower region includes a trapezoid shape. An embodiment further including a lower metal line vertically aligned with the homogeneous interconnect structure, directly contacting the homogeneous interconnect structure without a barrier layer. An embodiment further including a lower metal line vertically aligned below the homogeneous interconnect structure; and a barrier layer between the lower metal line and the homogeneous interconnect structure.

An embodiment of the present invention includes a semiconductor structure including a homogeneous interconnect structure embedded in a dielectric layer, where the homogeneous interconnect structure includes a first region vertically aligned above a second region, the first region includes a first width at an upper horizontal surface of the first region and a second width at a lower horizontal surface of the first region, where the first width is greater than the second width, and the second region includes a third width at an upper horizontal surface of the second region and a fourth width at a lower horizontal surface of the second region, wherein the third width is less than the fourth width. An embodiment where the second width and the third width are substantially similar. An embodiment further including a first barrier layer separating the homogeneous interconnect structure from the dielectric layer. An embodiment further including a barrier layer separating the homogeneous interconnect structure from the dielectric layer, where the barrier layer includes at least two different materials. An embodiment where the second region includes a substantially rectangular shape. An embodiment further including a lower metal line vertically aligned below the homogeneous interconnect structure directly contacting the homogeneous interconnect structure without a barrier layer. An embodiment further including a lower metal line vertically aligned below the homogeneous interconnect structure, and a barrier layer between the lower metal line and the homogeneous interconnect structure.

An embodiment of the present invention includes a method of forming a semiconductor structure, the method including forming a homogeneous interconnect structure embedded in a dielectric layer, where the homogeneous interconnect structure includes a first region vertically aligned above a second region, the first region includes a first width at an upper horizontal surface of the first region and a second width at a lower horizontal surface of the first region, where the first width is greater than the second width, and the second region includes a third width, where the third width is greater than the second width. An embodiment further including forming a first barrier layer separating the homogeneous interconnect structure from the dielectric layer. An embodiment further including forming a barrier layer separating the homogeneous interconnect structure from the dielectric layer, where the barrier layer includes at least two different materials. An embodiment where the second region includes a trapezoid shape. An embodiment further including forming a lower metal line vertically aligned below the homogeneous interconnect structure directly contacting the homogeneous interconnect structure without a barrier layer. An embodiment further including forming a lower metal line vertically aligned below the homogeneous interconnect structure, and a barrier layer between the lower metal line and the homogeneous interconnect structure. An embodiment further including forming an upper metal line vertically aligned above the homogeneous interconnect structure.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a homogeneous interconnect structure embedded in a dielectric layer, wherein the homogeneous interconnect structure comprises an upper region vertically aligned above a lower region;
the first region comprises a first width at an upper horizontal surface of the upper region and a second width at a lower horizontal surface of the upper region, wherein the first width is greater than the second width; and
the lower region comprises a third width, wherein the third width is greater than the second width.

2. The semiconductor structure according to claim 1, further comprising:
a first barrier layer separating the homogeneous interconnect structure from the dielectric layer.

3. The semiconductor structure according to claim 1, further comprising:
a barrier layer separating the homogeneous interconnect structure from the dielectric layer, wherein the barrier layer comprises at least two different materials.

4. The semiconductor structure according to claim 1, wherein the lower region comprises a trapezoid shape.

5. The semiconductor structure according to claim 1, further comprising:
a lower metal line vertically aligned with the homogeneous interconnect structure, directly contacting the homogeneous interconnect structure without a barrier layer.

6. The semiconductor structure according to claim 1, further comprising:
a lower metal line vertically aligned below the homogeneous interconnect structure; and a barrier layer between the lower metal line and the homogeneous interconnect structure.

7. A semiconductor structure comprising:
a homogeneous interconnect structure embedded in a dielectric layer, wherein the homogeneous interconnect structure comprises a first region vertically aligned above a second region;
the first region comprises a first width at an upper horizontal surface of the first region and a second width at a lower horizontal surface of the first region, wherein the first width is greater than the second width; and
the second region comprises a third width at an upper horizontal surface of the second region and a fourth width at a lower horizontal surface of the second region, wherein the third width is less than the fourth width.

8. The semiconductor structure according to claim 7, wherein the second width and the third width are substantially similar.

9. The semiconductor structure according to claim 7, further comprising:
a first barrier layer separating the homogeneous interconnect structure from the dielectric layer.

10. The semiconductor structure according to claim 7, further comprising:
a barrier layer separating the homogeneous interconnect structure from the dielectric layer, wherein the barrier layer comprises at least two different materials.

11. The semiconductor structure according to claim 7, wherein the second region comprises a substantially rectangular shape.

12. The semiconductor structure according to claim 7, further comprising:
a lower metal line vertically aligned below the homogeneous interconnect structure directly contacting the homogeneous interconnect structure without a barrier layer.

13. The semiconductor structure according to claim 7, further comprising:
a lower metal line vertically aligned below the homogeneous interconnect structure; and a barrier layer between the lower metal line and the homogeneous interconnect structure.

14. A method of forming a semiconductor structure, the method comprising:
forming a homogeneous interconnect structure embedded in a dielectric layer, wherein the homogeneous interconnect structure comprises a first region vertically aligned above a second region;
the first region comprises a first width at an upper horizontal surface of the first region and a second width at a lower horizontal surface of the first region, wherein the first width is greater than the second width; and
the second region comprises a third width, wherein the third width is greater than the second width.

15. The method according to claim 14, further comprising:
forming a first barrier layer separating the homogeneous interconnect structure from the dielectric layer.

16. The method according to claim 14, further comprising:
forming a barrier layer separating the homogeneous interconnect structure from the dielectric layer, wherein the barrier layer comprises at least two different materials.

17. The method according to claim 14, wherein the second region comprises a trapezoid shape.

18. The method according to claim 14, further comprising:
forming a lower metal line vertically aligned below the homogeneous interconnect structure directly contacting the homogeneous interconnect structure without a barrier layer.

19. The method according to claim 14, further comprising:
forming a lower metal line vertically aligned below the homogeneous interconnect structure; and a barrier layer between the lower metal line and the homogeneous interconnect structure.

20. The method according to claim 14, further comprising:
forming an upper metal line vertically aligned above the homogeneous interconnect structure.
